(19) United States
(12) Patent Application Publication
(10) Pub. No.: US 2025/0313954 A1
(43) Pub. Date: Oct. 9, 2025

(54) GAS INJECTORS FOR MOCVD/CVD SYSTEMS

(71) Applicant: VEECO INSTRUMENTS INC., Plainview, NY (US)

(72) Inventors: Ajit Paranjpe, Basking Ridge, NJ (US); Johannes Kaeppeler, Lontzen (BE); Alexander Lerner, San Jose, CA (US); Ahmed El-Desouky, Vienna, VA (US); Jeffrey Montgomery, East Brunswick, NJ (US); Eilis Taylor, San Jose, CA (US); Adrian Celaru, Plainview, NY (US); Juan Gamarra, Plainview, NY (US); Nikhil Joshi, Plainview, NY (US); Sami Obeid, Middlesex, NJ (US); Tae-Seok Lee, Hillsborough, NJ (US); Bojan Mitrovic, Friedberg (DE); Robert S. Maxwell, IV, Brooklyn, NY (US); Sandeep Krishnan, Princeton Junction, NJ (US); Andrew Hanser, Morristown, NJ (US); Robert Miller, Somerset, NJ (US); Tushar Gulati, Frederick, MD (US)

(73) Assignee: VEECO INSTRUMENTS INC., Plainview, NY (US)

(21) Appl. No.: 19/098,317

(22) Filed: Apr. 2, 2025

Related U.S. Application Data
(60) Provisional application No. 63/573,660, filed on Apr. 3, 2024.

(51) Int. Cl. C23C 16/455; B33Y 80/00; C23C 16/458

(52) U.S. Cl. CPC C23C 16/45563; B33Y 80/00; C23C 16/45591; C23C 16/4584

(57) ABSTRACT

A chemical vapor deposition system includes a reaction chamber having an exhaust system and a gas injector having at least one injection zone. The system further includes a heater assembly for heating the reaction chamber. In accordance with the present disclosure, the gas injector is additively manufactured to form a unitary body.

### CROSS-REFERENCE TO RELATED PATENT APPLICATIONS

This application is based on and claims priority to U.S. Provisional Patent Application 63/573,660, filed Apr. 3, 2024, the entire contents of which is incorporated by reference herein as if expressly set forth in its respective entirety herein.

### TECHNICAL FIELD

The present technology is generally related to semiconductor fabrication technology and, more particularly to chemical vapor deposition processing and associated systems and more particularly, to a chemical vapor deposition system that includes a gas injector that is additively manufactured to form a unitary body.

### BACKGROUND

Certain processes for fabrication of semiconductors can require a complex process for growing epitaxial layers to create multilayer semiconductor structures for use in fabrication of high-performance devices, such as light emitting diodes (LEDs), laser diodes, optical detectors, power electronics, and field effect transistors. In this process, the epitaxial layers are grown through a general process called chemical vapor deposition (CVD). One type of CVD process is called metal organic chemical vapor deposition (MOCVD). In MOCVD, reactant gases are introduced into a reaction chamber within a controlled environment that enables the reactor gas to react on a substrate (commonly referred to as a “wafer”) to grow thin epitaxial layers.

During epitaxial layer growth, several process parameters are controlled, such as temperature, pressure, and gas flow rate, to achieve desired quality in the epitaxial layers. Different layers are grown using different materials and process parameters. For example, devices formed from compound semiconductors such as III-V or IV-IV semiconductors, typically are formed by growing a series of distinct layers. In this process, the wafers are exposed to a combination of reactant gases, typically including a metal organic compound such as an alkyl source that includes a group III metal, such as aluminum (Al), gallium (Ga), indium (In), and combinations thereof, and a hydride source that includes a Group V element, such as nitrogen (N), phosphorus (P), arsenic (As), or antimony (Sb), typically in the form of NH₃, AsH₃, PH₃, or an Sb metalorganic, such as tetramethyl antimony. In the case of IV-IV at least two elements of Silicon (Si) and Carbon (C) and Germanium (Ge) are formed by typically used as hydrides for example SiH₄, Si₂H₆ C₂H₄, C₃H₈, GeH₄ or chlorine containing gases, such as SiH₂Cl₂ and SiHCl₃. Chlorine containing gases (e.g., Cl₂, HCl and CHₓCl₄₋ₓ where x=₀ to ₃ may also be added. Generally, the alkyl and hydride sources are combined with a carrier gas, such as nitrogen (N₂), Argon (Ar) and hydrogen (H₂), or a mixture of a combination of H₂ with N₂ or Ar which do not participate appreciably in the reaction. In these processes, the alkyl and hydride sources flow over the surface of the wafer and react with one another to form a III-V compound of the general formula In_{X}Ga_{Y}Al_{Z}N_{A}A_{SB}P_{C}Sb_{D}, where X+Y+Z equals approximately one, A+B+C+D equals approximately one, and each of X, Y, Z, A, B, C, and D can be between zero and one. In other processes, commonly referred to as “halide” or “chloride” processes, the Group III metal source is a volatile halide of the metal or metals, most commonly a chloride such as GaCl₂. In yet other processes, bismuth is used in place of some or all the other Group III metals.

A suitable substrate for the reaction can be in the form of a wafer having metallic, semiconducting, and/or insulating properties. In some processes, the wafer can be formed of sapphire, aluminum oxide, silicon (Si), silicon carbide (SiC), gallium arsenide (GaAs), indium phosphide (InP), indium arsenide (InAs), gallium phosphide (GaP), aluminum nitride (AlN), silicon dioxide (SiO2), and the like.

In a rotating disc reactor architecture-based CVD process chamber, one or more wafers are positioned within, commonly referred to as a “wafer carrier,” so that the top surface of each wafer in a rotating carousel is exposed, thereby providing a uniform exposure of the top surface of the wafer to the gaseous ambient within the reaction chamber for the deposition of semiconductor materials. The wafer carriers are typically machined out of a highly thermally conductive material such as graphite and are often coated with a protective layer of a material such as silicon carbide or tantalum carbide. Each wafer carrier has a set of circular indentations, or pockets, on its top surface in which individual wafers are placed. The wafer carrier is commonly rotated at a rotation speed on the order from about 10 to 1500 RPM or higher. While the wafer carrier is rotated, the reactant gases are introduced into the chamber from a gas distribution device, positioned upstream of the wafer carrier. The flowing gases pass downstream toward the wafer carrier and wafers, desirably in a laminar flow.

During the CVD process, the wafer carrier is maintained at a desired elevated temperature by heating elements, often positioned beneath the wafer carrier. Therefore, heat is transferred from the heating elements to the bottom surface of the wafer carrier and flows upwardly through the wafer carrier to the one or more wafers. Depending on the process, the temperature of the wafer carrier is maintained on the order of between about 550-1200° C. for GaN based films. Higher temperatures (e.g., up to about 1450° C.) are used for growth of AlN based films and lower temperatures (e.g., down to about 350° C.) are used for growth of AsP films. For some materials such as SiC, temperatures of 1600° C.-1700° C. are required. Other temperature ranges are suitable for other materials such as SiC, Si and SiGe or 2D materials such as graphene, and sulphides or selenides of tungsten and molybdenum. The reactive gases, however, are introduced into the chamber by the gas distribution device at a much lower temperature, typically about 200° C., or lower, to inhibit premature reaction of the gases.

The gas injector comprises the component of the system that is responsible for injection of one or more gases into the reaction chamber. The various gases used in the reaction chamber include a non-reactive purge gas which is used at the start and at the end of each deposition for accomplishing the above. The non-reactant purge gas is used to flush or purge unwanted gases from the reactor chamber. A carrier gas is used before, during, and after the actual growth cycle. The carrier gas maintains uniform flow condition in the reactor. As the reactant gases responsible for growth are added, the flow rate of the carrier gas remains steady. Hydrogen is most often used as a carrier gas. The reactant gases used depend on the application type.

### SUMMARY OF THE DISCLOSURE

In one embodiment, a chemical vapor deposition system includes a reaction chamber having an exhaust system and a gas injector having at least one injection zone. The system further includes a heater assembly for heating the reaction chamber. In accordance with the present disclosure, the gas injector is additively manufactured to form a unitary body.

The use of additive manufacturing allows for fine control over the structural features and architecture of the gas injector. In particular, additive manufacturing allows for the gas injector to have features and properties that are not possible using traditional manufacturing techniques, such as drilling (milling) one or more metal parts that are then assembled together as by welding, etc. Inherently, there are limitations with such traditional manufacturing techniques, including the formation of fine internal features, such as fluid flow channels, etc., that are in close proximity to one another and/or ones that have intricate, complex shapes and/or patterns internally within the body of the gas injector.

The use of additive manufacturing allows the gas injector to be formed as a monobloc (e.g., a monobloc of fused material) with all of the integral features, such as the gas and coolant circuits, to be formed as voids within the monobloc. This is in contrast to conventional design in which tens and tens of individual parts are assembled together and therefore, there are significant limitations to design and assembly of such parts to form the assembled gas injector.

The summary above is not intended to describe each illustrated embodiment or every implementation of the present disclosure. The figures and the detailed description that follow more particularly exemplify these embodiments.

### BRIEF DESCRIPTION OF THE DRAWINGS

The disclosure can be more completely understood in consideration of the following detailed description of various embodiments of the disclosure, in connection with the accompanying drawings, in which:

FIG. 1 is a cross-sectional view of a chemical vapor deposition system.

FIG. 2 is a partial side perspective view of an exemplary chemical vapor deposition system.

FIG. 3 is a front and side perspective view of a horizontal cross flow gas injector in accordance with one embodiment and manufactured as a unitary construction using additive manufacturing technology.

FIG. 4 is a rear and side perspective view of the horizontal cross flow gas injector.

FIG. 5 is a front view of the horizontal and vertical gas injection zones of the horizontal cross flow gas injector of FIG. 3.

FIG. 6A is a cross-sectional view of a baffle design incorporated into the horizontal cross flow gas injector of FIG. 3.

FIG. 6B is view of injector nozzles downstream of the baffles of FIG. 6A.

FIG. 7 is a side cross-sectional view of features that impart horizontal and vertical flow to the gas exiting the horizontal cross flow gas injector of FIG. 3.

FIG. 8 is a side cross-sectional view of one exemplary baffle design.

FIG. 9 is a cross-sectional view of a multi-wafer chemical vapor deposition system with crossflow gas injection as a result of a movable center gas injector, which is shown in a raised position.

FIG. 10 is a cross-sectional, schematic view depicting a centrally located multi-zone gas injector including at least two distinct zones for the distribution of reactant gases into a reaction chamber in a crossflow direction.

FIG. 11A is a plan view of a segmented cover plate.

FIGS. 11B and 11C are partial plan views of a two-piece susceptor with gas foil rotation features.

FIGS. 12A and 12B are cross-sectional views of a multi-zone center gas injector in accordance with another embodiment and manufactured as a single a unitary construction using additive manufacturing technology.

FIGS. 13A and 13B are side cross-sectional views of a multi-zone center gas injector showing internal, integral gas and coolant channels.

FIG. 14A is a side view of a top end of the multi-zone center gas injector.

FIG. 14B is a cross-sectional view of an outer peripheral section of the multi-zone center gas injector.

FIG. 15A is a bottom perspective view of the multi-zone center gas injector.

FIG. 15B is a top perspective view of the multi-zone center gas injector.

FIG. 16 is a side view of a five-zone center gas injector with its associated plenums.

FIG. 17 is a side perspective view of an exemplary location of the multi-zone center gas injector.

FIG. 18 is side perspective view showing a coolant circuit of the multi-zone center gas injector.

FIG. 19 is a cross-sectional view of a gas injector in accordance with another embodiment and manufactured as a single a unitary construction using additive manufacturing technology.

FIG. 20A is a cross-sectional close-up view of traditional gas injectors showing cooler channels.

FIG. 20B is a cross-sectional close-up view of several gas injectors of the injector of FIG. 19.

FIG. 21 is a cross-sectional view of a section of the injector of FIG. 19.

FIG. 22 is a rear and side perspective view of another horizontal cross flow gas injector.

FIG. 23 is a side cross-sectional view of another exemplary baffle design.

While embodiments of the disclosure are amenable to various modifications and alternative forms, specifics thereof shown by way of example in the drawings will be described in detail. It should be understood, however, that the intention is not to limit the disclosure to the particular embodiments described. On the contrary, the intention is to cover all modifications, equivalents, and alternatives falling within the spirit and scope of the subject matter as defined by the claims.

### DETAILED DESCRIPTION

As wafer sizes for III-V epitaxial growth have increased from 150 mm diameter wafers to larger diameter wafers, such as 200 mm and 300 mm diameter wafers, consumer preference has generally tended towards single wafer reactors, such as the PROPEL™ GaN MOCVD system, due to its superior uniformity and process control. An example embodiment of the PROPEL™ GaN MOCVD system is disclosed in US Pat. App. Publ. No. 2017/0067163, the contents of which are incorporated by reference herein. Advantages for single wafer reactors include rotational averaging for improved deposition uniformity without leading and/or trailing edge effects, low centripetal forces on the wafer, and a wide process window.

### CVD SiC Reactor

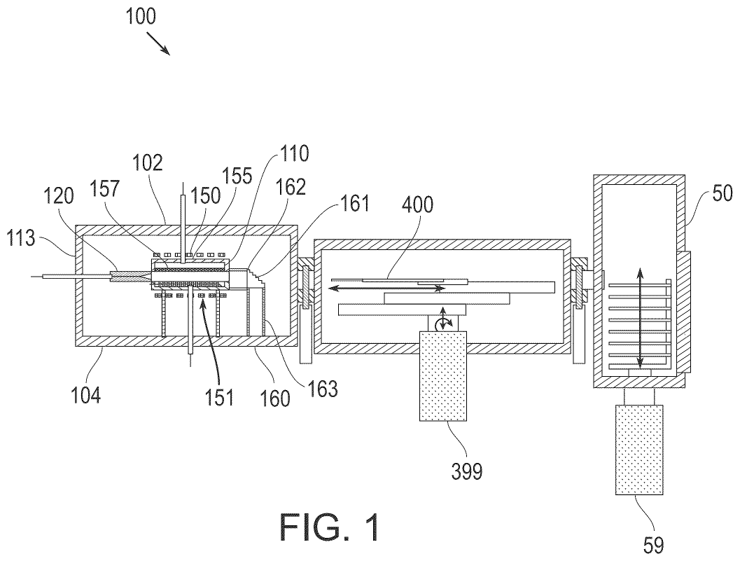

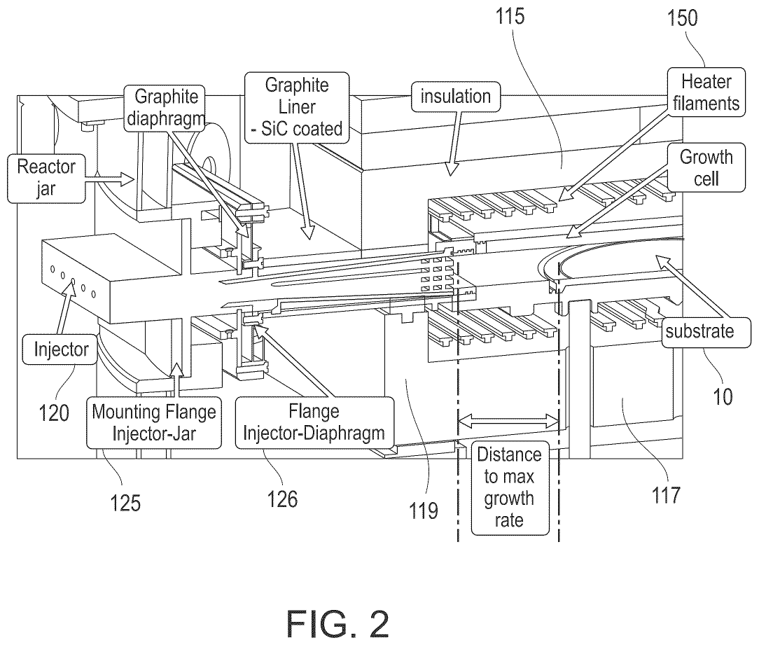

Referring to FIGS. 1-2, a chemical vapor deposition system 100 in the form of a single wafer, hot-wall, hybrid flow reactor for CVD SiC is depicted in accordance with an embodiment of the disclosure. The chemical vapor deposition system 100 includes a reaction chamber 110 (occasionally referred to herein as a “process chamber” or “reactor” or “reactor chamber”), configured to define a process environment space, in which an injector (gas injector) 120 (which alternatively can be referred to as a “gas distribution device”) can be arranged within the environment space. FIGS. 1-2 are simplified in order to more easily show certain basic features of the system, including internal components within the reaction chamber 110. The reaction chamber 110 is contained within a surrounding housing structure as shown. The reaction chamber 110 can also be described as being a growth cell.

As described herein and as is known, the system 100 includes one or more susceptors that hold and heat semiconductor wafers 10 (also referred to as a “wafer substrate”) (See, FIG. 2). The system 100 can thus be of a single wafer design or can be of a multi-wafer design as described below. As is known, a rotating susceptor holds a single wafer 10 and rotates it while the gases used in reaction chamber 110 flow over the wafer. It is called a susceptor because, in addition to holding the wafer, it is made of a suitable material, such as graphite, and can be inductively heated by an RF coil located outside the reactor cell or by resistance heated filaments outside the reactor cell, thereby controllably heating the wafer to the desired deposition temperature.

The present disclosure describes and illustrates both a single wafer design (single susceptor) as well as a planetary (multi-wafer) wafer design. The housing surrounding the reaction chamber 110 can have a conventional design and generally includes a top wall 102, an opposite bottom wall 104, along with a sidewall 113. With reference to FIG, 2, the reaction chamber 110 itself is similarly defined by a top wall 115, a bottom wall 117 and a sidewall 119.

Additional details concerning an exemplary SiC reactor are set forth in U.S. Pat. App. No. 63/428,250, filed Nov. 28, 2022, which is hereby incorporated by reference in its entirety.

### Gas Injector

The system 100 can include any number of different types of gas injectors and the system can include one or more gas injectors. As described, the gas injector(s) comprises the primary means for injecting different types of gases, both purge, carrier and reactant gases, into the reaction chamber 110. For example, FIGS. 1-8 illustrate one exemplary gas injector 120 that is a sidewall gas injector in that gas injected laterally from one sidewall into the reaction chamber 110. It will be appreciated that, as is known, a sidewall gas injector injects one or more gases into the reaction chamber 110 in a direction inward from the sidewall. As shown in FIGS. 1-2, the gas injector 120 can be located at one end of the reaction chamber 110 and can include a plurality of discharge openings or nozzles through which the one or more gases are injected into the interior of the reaction chamber 110. The discharge openings can be formed in a uniform or non-uniform manner and can be arranged in groups or zones.

It will also be appreciated that different process gases can be supplied to the various gas inlets of the gas injector 120. The gas injector 120 can be a water-cooled injector with the water cooling being achieved by water inlets and outlets that are formed in the gas injector block in which the gas inlets are formed. In such a case, water functions as the coolant.

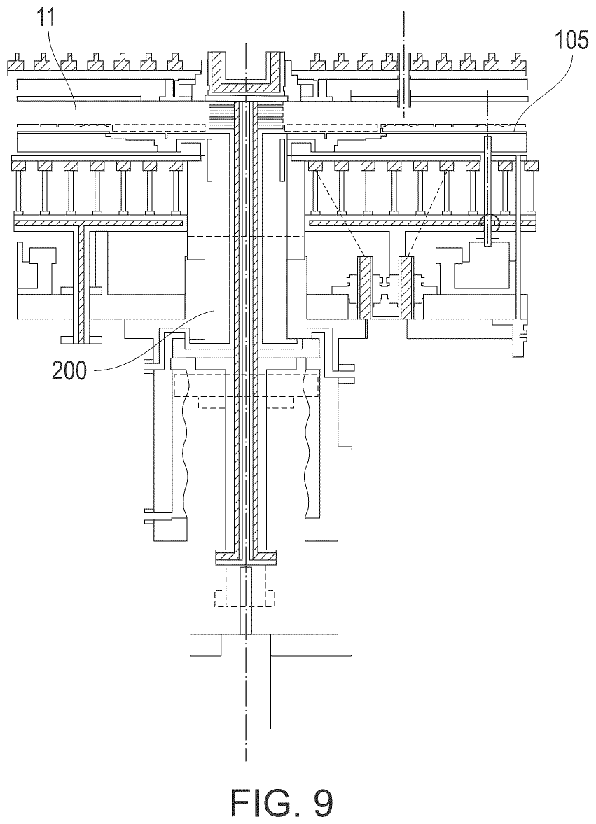

The gas injector 120 is thus connected to a gas delivery system for supplying process gases to be used in the chemical vapor deposition process, such as a carrier gas and one or more reactant gases such as a metal organic compound and a group V or a group IV source of reactants. Thereafter, the gas injector 120 can be configured to direct a flow of combined process gases into the process environment. In another embodiment shown in FIG. 9, the gas injector can be a centrally located multi-zone injector 200 for the distribution of reactant gases into the reaction chamber in a crossflow direction. One feature of the present disclosure is that the gases are maintained separately that allows for the gases to be routed in select flow paths and allows for tailored mixing. In yet another embodiment, the reactant gases are not mixed before entering the reactor and instead, each individual gas is injected into the reactor above the wafer and mixing of the gases occurs right above the wafer. Thus, the multi-zone injector disclosed herein allows for delivery of gases onto the wafer without pre-mixing. As described herein, the injector 120 can also be connected to a coolant system configured to circulate a liquid through the injector 120, to maintain the temperature of the process gas at a desired temperature during operation.

In one embodiment, H₂/HCl is injected through the gas injector 120 to minimize the deposition on the leading edge of the reactor ceiling and the reactor floor to an acceptable level. These portions of the reactor 110 are replaced only during a preventative maintenance that is performed after 1500 μm-3000 μm of cumulative deposition. Since a safe buildup amount is 300 μm over 3000 μm of deposition, the acceptable deposition rate on these surfaces should be <10% of the growth rate on the wafer or <5 μm/hr. for a growth rate of 50 μm/hr. on the wafer.

FIGS. 1-2 thus show one location for the gas injector 120 which is along one side or end of the reactor 110 to affect a substantially horizontal or crossflow of reactant gases over substrates (wafers) positioned within the reaction chamber 110.

Following introduction of the process gases into the reaction chamber 110, the process gas flows across a wafer carrier (which supports the wafer substrate (“wafer”) 10), and over the top surface of the wafer carrier, including an individual wafer supporting disc, where an individual wafer substrate 10 is held. Often the process gas in proximity to the top surface of the wafer carrier is predominantly composed of a carrier gas, such as H₂ and/or N₂, and/or Ar, with some amount of first or second reactive gas components. The first reactive gas component can be an alkyl source Group III metal, and the second reactive gas component can be a hydride source Group V element. For SiC deposition, the first reactive gas is typically a chlorosilane or a Silane with Hydrochloride while the second reactive gas is typically an alkane.

The flow of process gas continues to flow around a periphery of the wafer carrier and is eventually exhausted from the reaction chamber 110 through the exhaust system, via one or more ports located within the process environment space.

The system 100 can be thought of as including an upper (ceiling or lid) region and a lower (substrate) region. The upper region includes the ceiling of the reaction chamber 110, while the lower region contains the wafer carrier.

Along the sidewall 113 of the housing of the system, there is also a load port for loading and unloading the wafer carrier. In FIG.1, a robotic tool is used to automatically load and unload the single wafer carrier of FIG. 1 and each planetary wafer carrier of FIG. 9. In FIG. 1, the robotic tool comprises an end effector 400 that is configured to load and unload the wafer carrier with a motor 399 being provided to control movement of the end effector 400. FIG. 1 also illustrates a storage chamber 50 that is in selective communication with a transport chamber. Within the storage chamber 50 there is a storage shelf that can hold an object such as the wafer carrier with wafer. A lift motor 59 is operatively coupled to the storage shelf for raising and lowering the storage shelf.

### Horizontal Cross Flow Gas Injector

As described in more detail herein and with reference to FIGS. 1-8, today's gas injector solutions for high performance CVD/MOCVD systems are limited by design requirements either by increasing over proportional manufacturing costs for scaling up the gas injector of vertical reactors or by limitations in size to execute very compact gas injector restricted by its location in the reactor. The present disclosure describes a solution of using very efficient design for enabling laminar gas flow pattern together with efficient cooling of surfaces which are facing the hot susceptor area enabled by additive manufacturing (AM) techniques and technologies. AM allows for very compact space in horizontal or cross flow reactors. The gas feeding plenums and the coolant (water-cooling) channels must be optimized to be safely separated between both. By creating the plenums out of one piece by AM instead of multiple complex welding or sealings, the design will be much more compact and executed with thinner walls which is beneficial of maximum heat transfer and to a total size of the injector even with a larger number of separating gas feeding and cooling plenums.

In one embodiment, the gas injector 120 can comprise a horizontal cross flow gas injector that is shown in FIGS. 1-2 that is positioned at one end of the reaction chamber 110. As described herein, the gas injector 120 includes at least three and up to five inlet areas in a vertical direction and up to three horizontal (lateral) inlet zones. Each injection zone is configured to generate a laminar and uniform flow pattern into the growth zone.

The gas injector 120 includes a main unitary body 122 in which the gas inlets and cooling architecture are formed. The main body 122 can thus be thought to be an integral manifold for channeling and routing gas. In the present case, the main body 122 comprises a monobloc. For example, the main body 122 has a first (rear) end 123 and an opposite second (front) end 124 with one or more flanges in between these two ends. For example, the main body 122 can have a mounting flange 125 and a smaller diaphragm flange 126. FIG. 2 shows a cross-section of one exemplary reactor and show the mounting flange 125 seating against the reactor jar and the diaphragm flange 126 seating against a diaphragm, e.g., a graphite diaphragm.

The first end 123 can be considered to be an inlet end in that the one or more gases are introduced into the gas injector 120 and the second end 124 is an outlet end in which the one or more gases exit the gas injector 120 at predefined locations and according to predefined patterns into the reaction chamber 110. As mentioned herein, the gas injector 120 also includes a cooling feature in that the main body 122 has a coolant circuit defined by coolant/cooling channels in which a coolant (cooling fluid) circulates for cooling the main body 122 and thus for cooling of the gas injector. The coolant can be any number of suitable cooling fluids, including but not limited to, water, glycol, or the like. Since the coolant runs in a closed loop through the main body 122, the coolant enters into the main body 122, is circulated therethrough, and then exits the main body 122. For example, the main body 122 can include one or more coolant inlets that are open along the first end 123 and can have one or more coolant outlets formed along the first end 123. For ease of illustration, the one or more coolant inlets and outlets are generally indicated at reference number 127 (FIG. 4) (which can be spread out across the width of the first end 123). As mentioned, along the first end 123, there are also one or more gas inlets that are interspersed between the one or more coolant inlets and outlets 127.

The second end 124 can have at least a portion that has a trapezoidal shape that matches the reaction chamber 110.

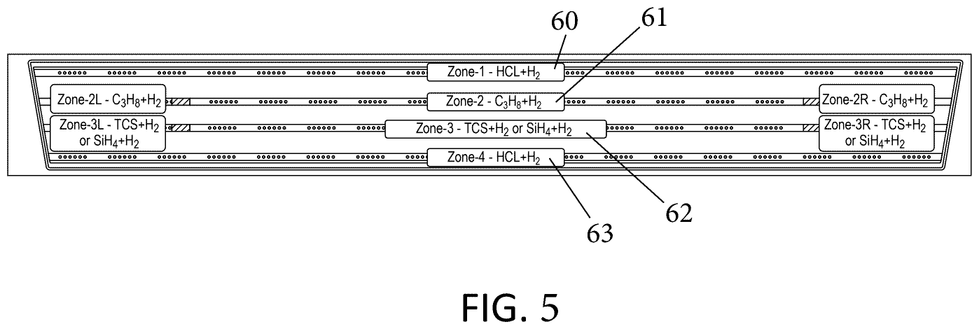

In one embodiment, the gas channel architecture of the main body 122 is such that a plurality of gases enter through gas inlets and are routed through gas channels formed in the main body and exit through gas outlets that are arranged in at least three or up to five gas outlet areas in vertical direction and up to three horizontal outlet zones. Each injection zone must be generating a laminar and uniform flow pattern into the growth zone. For example, in the embodiment illustrated in FIG. 5, there are eight gas outlet zones in which the one or more gases exit the gas injector 120 into the reaction chamber 110. For example, there can be a first zone 60, a second zone 61, a third zone 62 and a fourth zone 63. The first to fourth zones 60-63 are vertical zones in that they are arranged in a stack relationship with the first zone 60 being the top zone and the fourth zone 63 being the bottom zone. In other words, there are four outlet zones in the vertical direction. Moreover, the one or more gases are dispersed across multiple horizontal zones. For example, in the illustrated embodiment, the first zone 60 and the fourth zone 63 only include a single outlet zone in the horizontal direction (e.g., a center oriented single outlet zone). In contrast, each of the second and third zones 61, 62 includes multiple horizontal zones. For example, each of the second zone 61 and the third zone 62 can include three horizontal zones (e.g., 2L, 2, 2R and 3L, 3, 3R).

In the illustrated embodiment, the first and fourth zones 60, 63 comprise upper and lower gas purge zones in which a purge gas, such as HCl+H₂ is injected into the reaction chamber 110. Zones 2L, 2, 2R can be used to inject C₃H₈+H₂ into the reaction chamber 110. Zones 3L, 3, 3R can be used to inject trichlorosilane (TCS)+H₂ or SiH₄+H₂ into the reaction chamber 110. It will be appreciated that these purge and reactant gases are merely exemplary in nature and other gases and/or other gas combinations can be injected into the reaction chamber 110 through the main body 122. The coolant circuit is an integral feature formed in the one-piece main body 122.

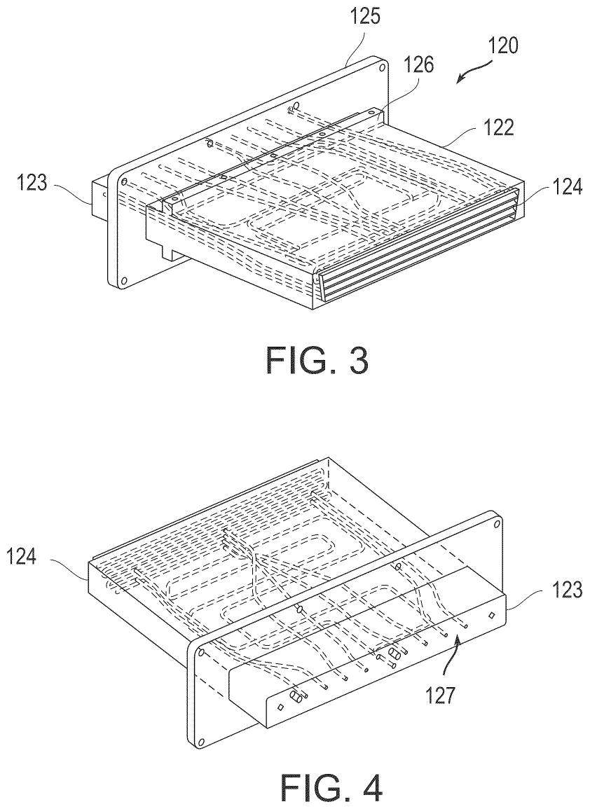

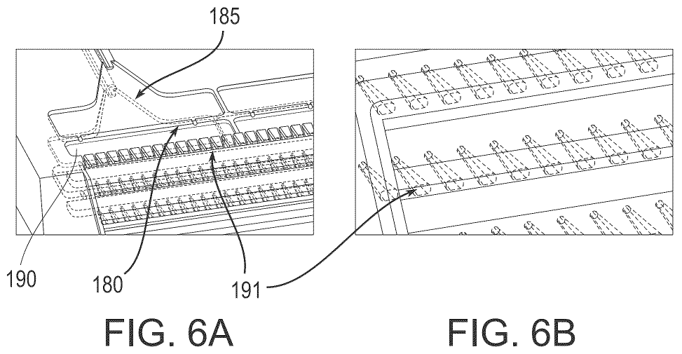

Now referring to FIGS. 3-8, as mentioned, each injection zone (i.e., the area at which the gas exits the main body 122 along the second end 124 thereof) is configured and enables a horizontal flow and a uniform flow pattern in horizontal direction. To achieve these objectives from a flow distribution from a round hole (e.g., one gas inlet along the first end 123) coming from each gas supply line (connected to a source of the gas), flow modifying features are incorporated into the flow path of the gas within the main body 122. For example, as described herein, one flow modifying feature can be configured to promote and expand the horizontal flow of the gas, while another flow modifying feature can be configured to execute the vertical distribution of the gas. More particularly, one flow modifying feature can be in the form of one or more and preferably a plurality of baffles 180 that are designed into the flow path of the gas to distribute a wide slit homogeneous flow as shown in FIGS. 6A and 6B. As shown, a substantial length of each gas flow path (channel) within the main body 122 can have a conduit shape (e.g., cylindrical shape) that leads to a gas inject space (volume) 185 that is a much larger area than the conduit. As shown, the gas inject space 185 has an expanded horizontal dimension compared to the cylindrical shaped gas conduit. For example, as the gas enters into the gas inject space 185 from the cylindrical shaped gas conduit, the gas flows radially outward and laterally into the larger gas inject space 185. The gas inject space 185 thus serves to expand the horizontal flow of the gas. The gas inject space 185 is in fluid communication with a plurality of outlet holes 189 and therefore, a single cylindrical spaced gas conduit through which the gas enters the main body 122 feeds a plurality of outlet holes 189 downstream of the baffle(s) 180. In this manner, the gas can be horizontally expanded and can flow into different lateral zones as generally depicted in FIG. 5.

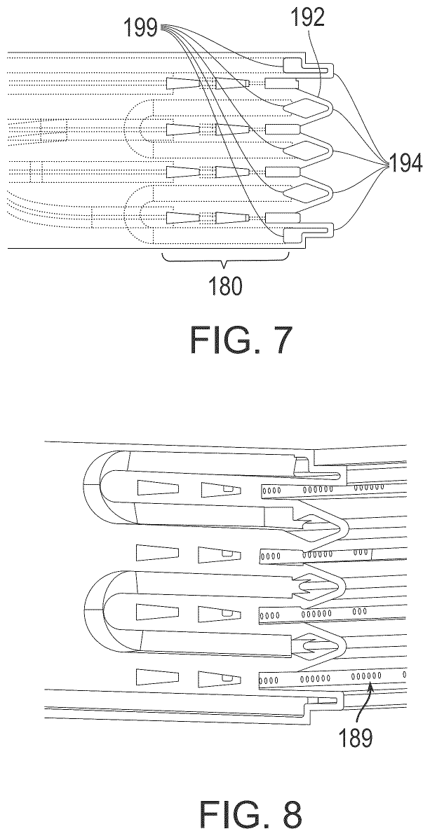

Downstream of the baffle 180 feature that expands the horizontal flow of the gas there is a feature, as mentioned above, that vertically distributes the gas. This allows the gas to be directed and to flow into multiple vertical zones (each injection zone having its own vertical gas distribution feature). In the illustrated embodiment, to execute the vertical distribution the outlet holes 189 are entering an open space 190 with chamfered side walls 192 ending in fins 194. As shown in the side cross-sectional view of FIG. 7, the fins 194 are stacked vertically and thus, the open space 190 is defined by a top fin 194 and a bottom fin 194. The top fin 194 has a surface that is angled upward, while the bottom fin 194 has a fin that is angled downward and therefore, when the gas flows into the open space 190, the gas expands in a vertical direction. The fins 194 thus in part define gas inject nozzles 191 for injecting the gas into the reaction chamber 110.

Accordingly, the use of baffles 180 and fins 194 provides for both horizontal and vertical expansion of the gas that is injected into the reaction chamber 110.

As also shown in the drawings, the gas conduits that are formed in the main body 120 can be formed in different planes. In other words, the gas conduits that are open at the first end 123 themselves can be in a stacked arrangement which assists in formation of the vertical gas distribution zones at the opposite second end 124.

The chamfered side walls 192 ending in fins 194 convert the outlet holes 189 into gas injection nozzles 191 in that the gas exiting the outlet holes 189 vertically expands due to the chamfered side walls 192 and the gas is injected into the reaction chamber 110. In the gas injector 120, the injection nozzles are arranged in rows and can be linearly formed in stacked arrangement.

Since the entire gas injector 120 is formed as a monobloc (unitary construction), all of the aforementioned features, such as gas channels, baffles, and fins, are formed integrally within the monobloc as voids and/or contoured surfaces.

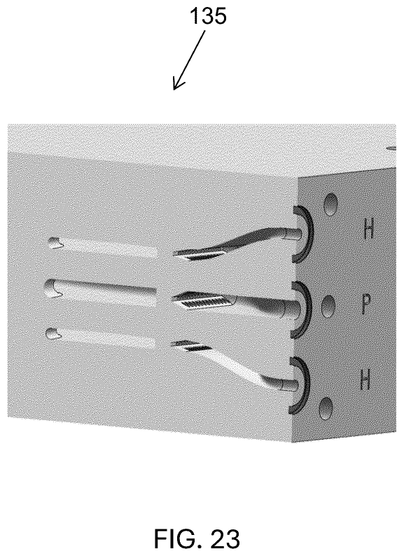

FIG. 23 illustrates an alternative baffle design 135 to that shown in FIG. 8. The functionality of the baffle design and gas delivery architecture in FIG. 23 is similar to that described with reference to FIG. 8.

### Cooling Architecture

As mentioned, the main body 122 includes integral cooling features that are formed therein and more specifically, the cooling is delivered into the main body 122 through the one or more coolant inlets 127 that are open along the first end 123 and after flowing through the coolant circuit, the coolant exits the main body 122 through the one or more coolant outlets 127. The coolant circuit is strategically formed to achieve the intended objectives. The coolant circuit can be and is preferably formed in multiple (horizontal) planes, thereby allowing the coolant circuit to be located both above and below the gas conduits formed in the main body 122. The coolant circuit can take any number of custom shapes, including having at least a serpentine shaped section. In particular, as shown in FIG. 4, the serpentine shaped section can be located upstream of the baffles 180 and can be in proximate to the conduit sections of the gas channels.

In one aspect, the fins 194 contain coolant channel (sections) 199 (FIG. 7) to get an efficient cooling at the second end 124 of the main body 122 that is located inside and is exposed to the reaction chamber 110. In other words, the coolant channels are located at the locations of the gas injection nozzles to provide for cooling of the second end 124 of the main body 122.

In one aspect of the present disclosure, the coolant channels can have multiple shapes along their lengths. For example, the coolant channels can have cylindrical shapes near the first end 123 but within the fins 194, the coolant channels can have diamond shapes. The diamond shape is complementary to and mirrors the chamfered side walls 192. It will also be seen that coolant channels outside of the fins 194 can have non-diamond shapes. For example, the topmost coolant channel and the bottommost coolant channel can have non-diamond shapes.

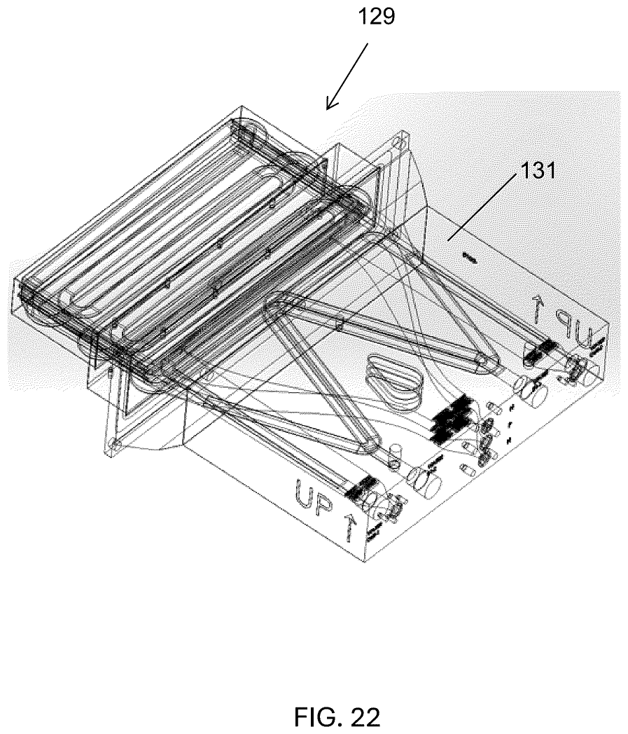

FIG. 22 illustrates another embodiment that is similar to the embodiment of FIG. 4. More particularly, FIG. 22 illustrates a gas injector 129 that has different internal architecture but is similar to the gas injector 120 of FIG. 4. In other words, the gas injector 129 includes integral gas inlets and gas nozzles and cooling architecture formed therein. The gas injector 129 can include at least three and up to five inlet areas in a vertical direction and up to three horizontal (lateral) inlet zones. Each injection zone is configured to generate a laminar and uniform flow pattern into the growth zone.

The gas injector 129, like injector 124, includes a main unitary body 131 in which the gas inlets and cooling architecture are formed. The main body can thus be thought to be an integral manifold for channeling and routing gas. In the present case, the main body 131 comprises a monobloc. For example, the main body 131 has a first (rear) end and an opposite second (front) end and can have one or more flanges in between these two ends.

The first end can be considered to be an inlet end in that the one or more gases are introduced into the gas injector 129 and the second end is an outlet end in which the one or more gases exit the gas injector 129 at predefined locations and according to predefined patterns into the reaction chamber 110 much like injector 124. As mentioned herein, the gas injector 129 also includes a cooling feature in that the main body 131 has a coolant circuit defined by coolant/cooling channels in which a coolant (cooling fluid) circulates for cooling the main body 131 and thus for cooling of the gas injector. The coolant can be any number of suitable cooling fluids, including but not limited to, water, glycol, or the like. Since the coolant runs in a closed loop through the main body 131, the coolant enters into the main body 131, is circulated therethrough, and then exits the main body 131. For example, the main body 131 can include one or more coolant inlets that are open along the first end and can have one or more coolant outlets formed along the first end.

A comparison between FIG. 4 and FIG. 22 illustrates that the use of additive manufacturing modeling and fabrication allows for different internal gas channel architecture and different internal coolant architecture. It will be appreciated that additive manufacturing allows for may different types of architectures to be modeled and fabricated.

### Additive Manufacturing

In accordance with the present disclosure, the gas injector 120 is manufactured by additive manufacturing technology. The term “additive manufacturing” references technologies that grow three-dimensional objects one superfine layer at a time. Each successive layer bonds to the preceding layer of melted, partially melted, or otherwise fused material. Objects are digitally defined by computer-aided-design (CAD) software that is used to create .stl files that essentially “slice” the object into ultra-thin layers. This information guides the path of a nozzle or print head as it precisely deposits material upon the preceding layer. Alternatively, an energy source such as a laser or electron beam selectively melts or partially melts in a bed of powdered material. As materials cool or are cured, they fuse together to form a three-dimensional object.

As discussed herein, the use of additive manufacturing allows for fine control over the structural features and architecture of the gas injector. In particular, additive manufacturing allows for the gas injector to have features and properties that are not possible using traditional manufacturing techniques, such as drilling (milling) one or more metal parts that are then assembled together as by welding, or other joining techniques. Inherently, there are limitations with such traditional manufacturing techniques, including the ability to form fine internal features, such as fluid flow channels, etc., that are in close proximity to one another and/or ones that have intricate, complex shapes and/or patterns internally within the body of the gas injector. Additionally, the creation of these features by joining separate bodies introduces leak points.

The use of additive manufacturing allows the gas injector to be formed as a monobloc (e.g., a monobloc of fused material) with all of the integral features, such as the gas and coolant circuits, to be formed as voids within the monobloc. This is in contrast to conventional design in which tens and tens of individual parts are assembled together and therefore, there are significant limitations to design and assembly of such parts to form the assembled gas injector. For example, in conventional gas injector design, it is often difficult to incorporate bends along the conduit, etc.

Thus, unlike traditional design, the use of additive manufacturing permits both the gas circuit and the coolant circuit to have a more complex shape including curvature and bends along its length and also the coolant circuit can be formed in closer proximity to the gas channels. One advantage of additive manufacturing is the degree of customization of the channel architecture for both the gas and coolant. Modeling software (3D modeling and design) can be used to develop and create the design of the internal gas and coolant channel architecture without the significant limitations that existed in prior manufacturing techniques of combining multiple parts and/or boring metal parts to form internal channels.

### Center Cross-Flow Injector 200

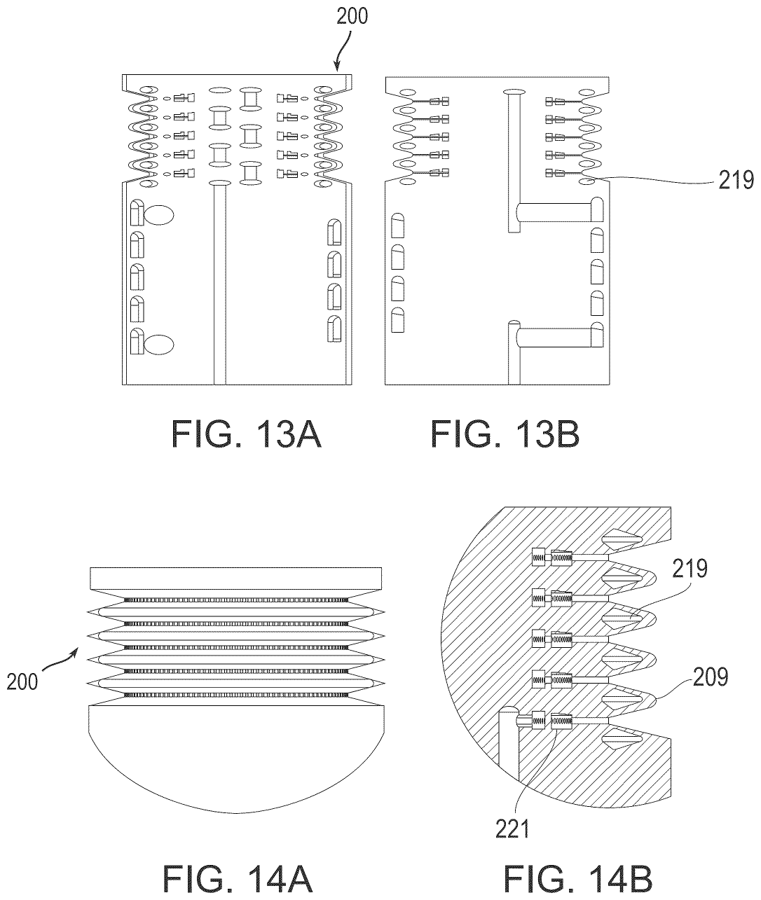

In alternate embodiments, as illustrated in FIGS. 9-10 and 12A-18, the gas injector can be in the form of a vertically movable gas injector 200 that is centrally positioned within a reaction chamber 111 (that can be similar to reaction chamber 110) to affect a substantially horizontal or crossflow of reactant gases over substrates positioned within the reaction chamber 110. The gas injector 200, like the gas injector 120, is formed using additive manufacturing techniques and thus, as described herein, can be configured and designed using modeling software. The internal channeling including gas distribution channels and coolant channels are thus voids formed in the single block structure.

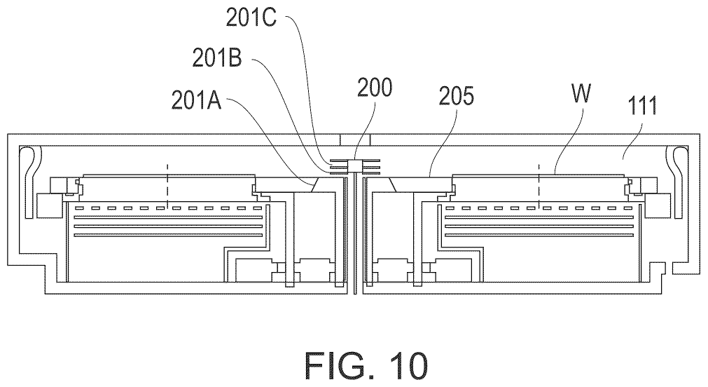

For example, with reference to FIGS. 9-10, a multi-zone injector 200 can be positioned adjacent to the top surface of the wafer carrier 105, so as to have a lateral component with respect to the one or more substrate wafers positioned within the wafer carrier 105. As such, the injector 200 can provide a variable horizontal flow of reactant gas towards exposed growth surfaces of the one or more substrate wafers. As described herein, the multi-zone center injector 200 can be raised and lowered between a load and unloading position, which is the lowered position, in which the wafer carrier 105 can be loaded and unloaded through the load port and a process position, which is the raised position, in which reactant gas flows horizontally out of the injector 200 in a radially outward direction over the wafers that are located on the satellites.

The gas injector 200 can be considered to provide a horizontal concentric gas inlet with multiple zones for injecting the reactant (process) gases into the reaction chamber 110 with planetary rotation of the satellites to compensate for precursor depletion.

In some embodiments, the centrally located injector 200 can be temperature controlled via the coolant system and can be connected to gas sources for independently introducing one or more of a first reactant gas, second reactant gas, and/or inert gases into the reaction chamber 110. Further, the injector 200 can comprise multiple injection zones stacked vertically with dividers, such as baffles/fins 209, separating the injection zones from one another. For example, in one embodiment, the injector 200 can include a plurality of stacked inlets 201A-E for injection of the respective first reactant gas, second reactant gas, etc., and inert gases into the reaction chamber 111. In one embodiment, the center injector 200 is a five-zone injector that provides good uniformity (thickness and doping) at high growth rates (50 μm/hr). In the raised position, all zones (all of the inlets) are exposed and activated to allow unimpeded flow of the reactant gas from each of the inlets. Conversely, in the lowered position, none of the zones are activated and all of the inlets are closed off.

In some embodiments, the inlets 201A-E can be separated by horizontally oriented baffles (fins 209) configured to enable separation of the process gases into independently regulatable vertical zones. In embodiments, the zones can be externally plumbed, so that the zones can operate individually or be ganged together into zones with the appropriate gas mixture fed to each of the zones. In the illustrated embodiment, the gas inlet zones are as follows:
201A: H₂+HCl,
201B: H₂+SiH₄ or TCS or DCS
201C: H₂+C₃H₈ or another Alkane
201D: H₂+SiH₄ or TCS or DCS
201E: H₂+HCl,+doping gas (N₂ or TMAl . . . )

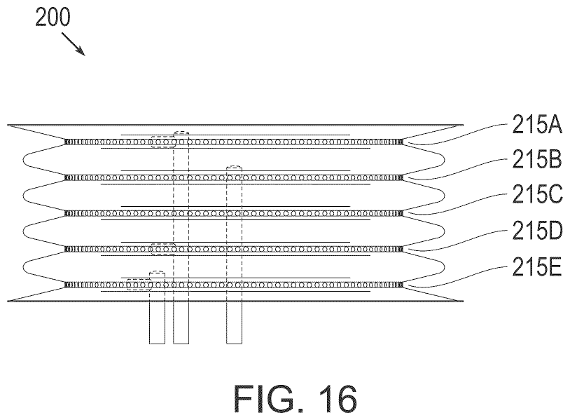

FIG. 16 illustrates corresponding plenums (gas delivery conduits) that are associated with the injection zones. For example, for the five-zone injector shown, there are five plenums 215A-E that serve to deliver the individual gases to their respective injection zones. Thus, plenum 215A is in fluid communication with the first injection zone, plenum 215B is in fluid communication with the second injection zone, plenum 215C is in fluid communication with the third injection zone, plenum 215D is in fluid communication with the fourth injection zone, and plenum 215D is in fluid communication with the fifth injection zone. It will be appreciated that in certain embodiments, the same gas can flow within two or more of the plenums 215A-E in the event that the same gas is injected into the reaction chamber 110 from different injection zones. Within each injection zone, the gas is distributed in an annular shaped manner before exiting through the gas outlets (e.g., gas injection nozzles) into the reaction chamber 110. The injection nozzles are arranged in a circumferential manner. As shown, each plenum 215A-215E can be defined by series of gas discharge outlets (injector holes) that are formed in the block. The gas discharge outlets can be arranged in an annular shape about the block. Thus, each injection zone has a ring of gas discharge outlets separated by the fins 209.

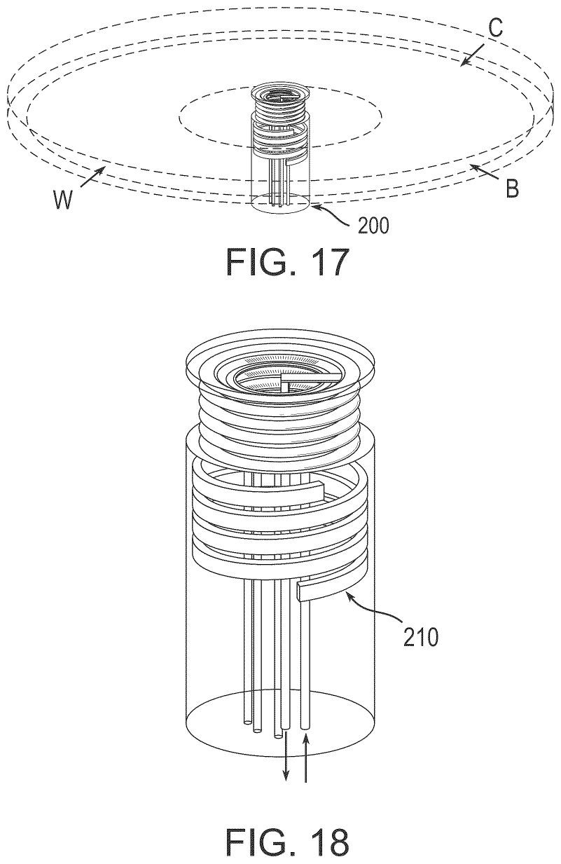

FIG. 17 illustrates the center injector 200 located central to the wafer carrier W. The center injector 200 can be formed of a suitable material and as mentioned, includes water and gas channels formed therein. The wafer carrier W can be at temperature of about 1650° C. and a ceiling C is also illustrated, which can be at a temperate of about 1700° C. An Adiabatic outer boundary is present at location B.

Each gas delivery conduit includes an integral vertical component that carries the gas to the respective gas injection zone. The gas delivery conduit can deliver the gas to one location within the gas injection zone and then it flows in an annular manner and radially outward to the multiple gas nozzles through which the gas is injected into the reaction chamber 111. In FIG. 14B, the reference character 221 shows one integral gas delivery conduit for routing gas to one zone. As mentioned, the internal architecture and flow path for each zone can be independent from the other zones and therefore, the different gas can be delivered into the different internal architecture (flow paths) to deliver different gases to the different zones.

In another embodiment, the injector 200 includes a predetermined number of vertically stacked zones. The zones can be assigned as inert gas (zone one), hydride (zone two), alkyl (zone three), hydride (zone four), and inert gas (zone five, zone six, zone seven). In another embodiment, the zones may be assigned as inert gas (zone one), hydride (zone two), alkyl (zone three), hydride (zone four), alkyl (zone five), hydride (zone six), and inert gas (zone seven). Another possible configuration is inert gas (zone one), hydride (zone two), alkyl (zone three, zone four), hydride (zone five, zone six), and inert gas (zone seven). Other embodiments are also contemplated.

In some embodiments, the gas injector 200 can include additional inlets for improved tunability of multi-gas flow ratios and concentrations. For example, in one embodiment, the injector 200 can include one or more vertical partitions configured to enable separation of the process gases into independently regulatable horizontal zones. In other embodiments, the injector 200 can include a combination of horizontally and vertically oriented baffles for improved tunability of multi-gas flow ratios and concentrations (similar to the previously described gas injector 120).

In embodiments, the injector 200 can be centrally located within the reaction chamber 111. Accordingly, reactant gases can be introduced into the reaction chamber via inlets 201A-E to provide a crossflow flow component of reactant gases across an exposed growth surface of one or more substrate wafers positioned within one or more pockets of the wafer carrier 105. In some embodiments, the injector 200 can be mounted on a bellows assembly, so that the injector 102 can be moved vertically up and down relative to the wafer carrier 105 to facilitate ease in removal of the wafer carrier 105 between epitaxial growth cycles. In other embodiments, the injector 200 can be positioned in proximity to a periphery of the wafer carrier 105.

It will also be appreciated that the center injector 200, that affect a substantially horizontal or crossflow of reactant gases over substrates positioned within the reaction chamber 110, is used in combination with the showerhead gas inlet arrangement, discussed herein, that introduces gases into the reaction chamber 110 from the ceiling location.

As with the gas injector 120, the center (gas) injector 200 is manufactured using additive manufacturing technology. This results in the center injector 200 being formed of a unitary construction (e.g., seamless unitary construction).

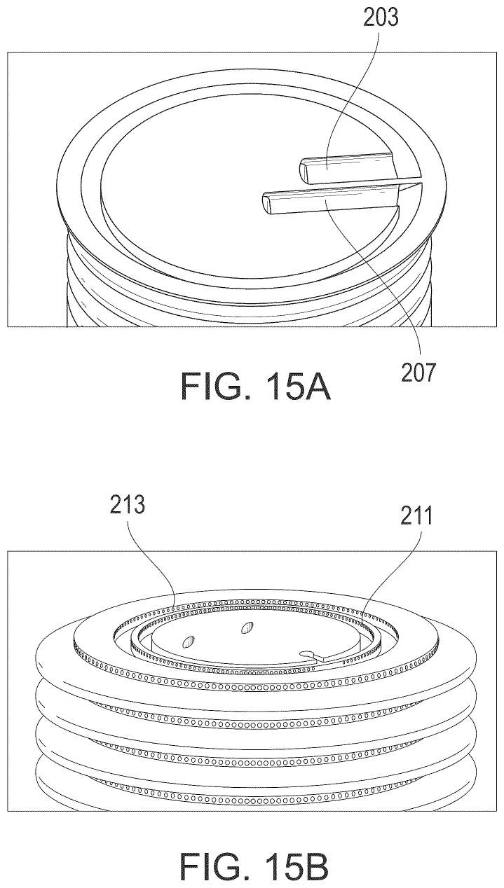

Moreover, like the gas injector 120, the center injector 200 includes an integral coolant circuit. The use of additive manufacturing to create the center injector 200 permits the center injector 200 to have a single coolant (water) loop to cool the center injector 200. As illustrated, the coolant circuit in the center injector 200 can include one or more of the following features: a coolant inlet 203 and coolant outlet 207 at the bottom as shown in FIG. 15A; spiraling coolant channels 210 to cool the injector body; swept coolant lines to decrease the pressure drop; and swept gas lines that are separate for each of the five gas channels. In other words, there are multiple coolant channels that run not only in the main body of the gas injector 200 but also channels that are located within the gas injection zones, such as the annular shaped ones that are formed in the fins that define the gas injection zones. This arrangement is shown in FIG. 18. All channels are in the form of voids in the single block of material formed by additive manufacturing.

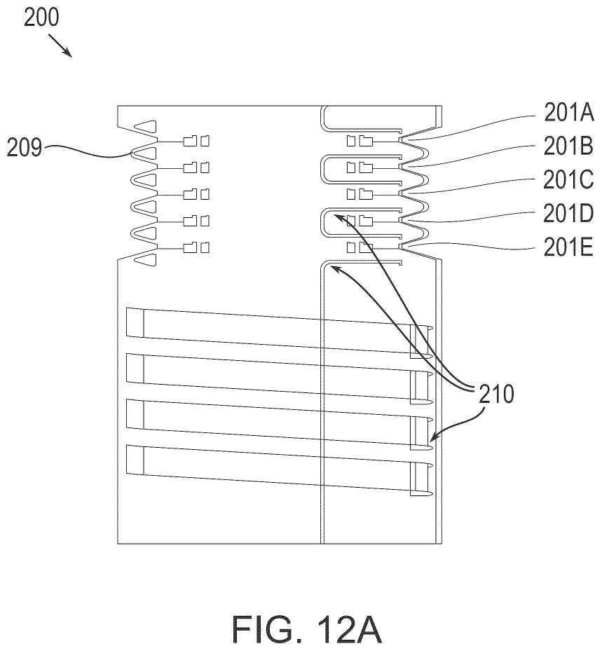

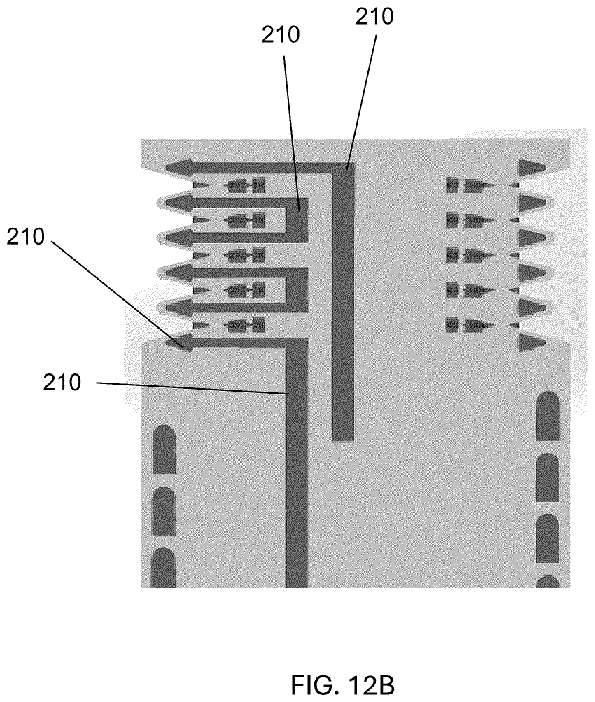

FIG. 12B further illustrates another water channel architecture that can be formed using additive manufacturing. As mentioned, a single loop coolant circuit (spiraling coolant channels 210) can be formed in the block. As shown, these water channels lead to and cool the fin areas along with other areas.

FIG. 14B illustrates the fins 209. As shown, the fins 209 contain coolant channels (sections) 219 to get an efficient cooling at the fin end that is located inside and is exposed to the reaction chamber 110. In other words, the coolant channels are located at the locations of the gas injection nozzles to provide for cooling of the gas injection structures. It will be appreciated that this cooling structure including the channels 219 are part of the single coolant loop that is formed in the single block of material that defines center injector 200. Thus, the single coolant loop routes the coolant (e.g., water) within the injector 200 to target locations, including coolant channels 219 within the fins 209.

Since the gas injector 200 comprises a single monolithic part, the voids formed therein define the gas channels, coolant channels, baffles for uniform gas distribution, etc. This again is in direct contrast to conventional designs in which multiple parts are provided and assembled to form the gas injector. As mentioned above, the coolant circuit can pass through the fins 209 that are defined by chamfered walls to direct the gas in a vertical direction. In addition, FIG. 15B illustrates an exemplary gas distribution through a baffle wall 211. As shown, the baffle wall 211 is located between a center section and an annular shaped outer section in which injector holes 213 are formed. As mentioned herein, the use of baffles is to promote uniform gas distribution from the gas injector 200. For example, similar to the baffle arrangement in FIG. 6A, the baffle wall 211 can be configured to impart horizontal flow to the gas and the fins that are radially outward therefrom impart vertical flow to the gas.

Thus, the center injector 200 illustrates the application of additive manufacturing in that intricate gas delivery conduits and intricate coolant channeling can be formed and can have shapes, etc., that are not possible using conventional gas injector fabrication technology. Additive manufacturing allows for complex channel modeling and fabrication.

The center injector 200 thus functions like traditional center injectors.

### Gas Injector 300 for Nitride Applications

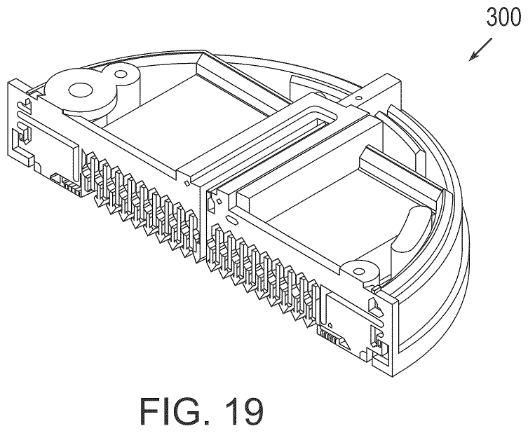

In alternate embodiments, as illustrated in FIGS. 19-21, a gas injector 300 is provided. As with the other gas injectors described herein, the gas injector 300 is formed using additive manufacturing techniques and thus, as described herein, can be configured and designed using modeling software. Conventional injector design for similar reactor applications comprises a substantial number of parts that are assembled together. The assembly is complex given the significant number of parts and also, there are structural limitations with the shape of the parts and layout given the vast numbers of parts required and the assembly of these parts in a relatively compact space. Conventional machining techniques are used to produce these parts.

As in the other embodiments and as a result of the gas injector 300 being formed by additive manufacturing, the gas injector 300 is formed as a unitary construction (e.g., seamless unitary construction). In other words, the gas injector is formed as an integral single block having voids formed therein to define internal features/components, such as channels, etc. By forming the gas injector 300 with an additive manufacturing process, a number of advantages are realized including but not limited to: a significant reduction in parts and assembly; elimination of process leak paths and crosstalk; cost reduction; and it provides a design capability that is unavailable with conventional machining.

As shown in FIGS. 19-21, the gas injector 300 includes a plurality of injector channels that are integrally formed therein and more specifically, are formed as voids during the additive manufacturing process. The advantages of forming voids for channels and other internal structures is described herein and is contrast to conventional formation techniques, in which physical conduits or complicated and limited bores were used.

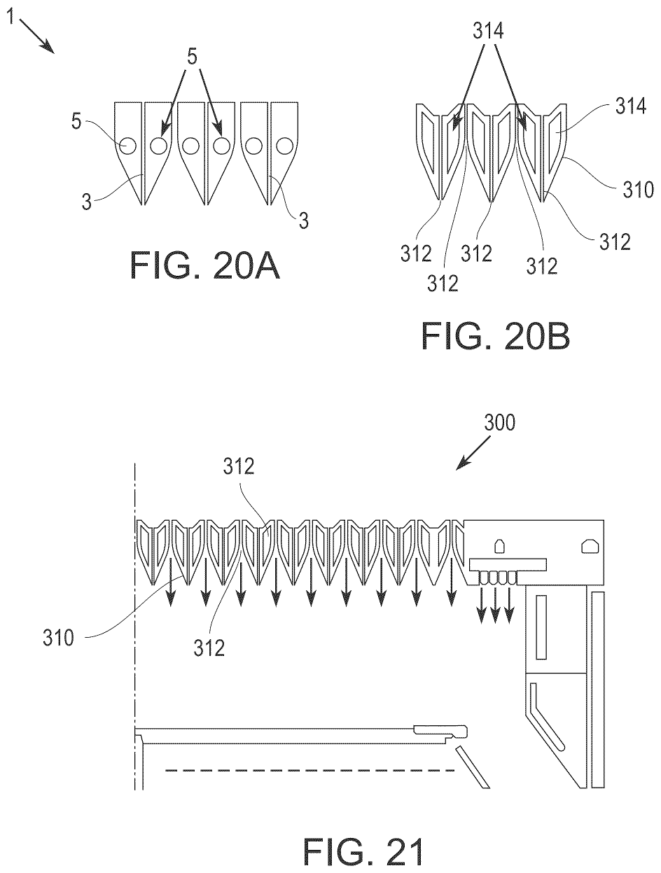

FIG. 20A shows a traditional array of gas injectors (nozzles) 1 with each gas injector 1 including a gas channel 3 and coolant channels 5. In the traditional fabrication of the gas injector 1, the coolant channels 5 are drilled holes and thus, there are limitations on this fabrication method.

These limitations result in the coolant channels 5 being small, which in turn results in the tips of each gas injector 1 being hot. In contrast, FIG. 20B shows an array of gas injectors (nozzles) 310 that are part of the overall gas injector 300. Each gas injector 310 includes a gas channel 312 and coolant channels 314 (e.g., water channels). Unlike the coolant channels 5, the coolant channels 314 have much greater area since they are formed by additive manufacturing which allows much more precision over the fabrication and footprint of the coolant channels 314. By having larger coolant channels 314, the injector tips are cooler which is an improvement and advantage over the traditional ones shown in FIG. 20A. As can be seen in FIG. 20B, there can be a plurality of different types of gas flows. For example, a first gas flow can be through an internal channel 312 in the nozzle, while another gas flow 312 can be between nozzles. This allows different reactive gases to flow in different flow paths (streams).

The gas channels 312 can distribute one or more gases similar to the previous embodiments. For example, the gas channels 312 can comprise the following: alkyl gas channels; hydride gas channels; channels associated with an inner shutter purge (ISP); an outer shutter purge (OSP); and viewport purge (VPP). The coolant channels 314 that carry coolant, such as water, are larger and are located closer to the alkyl exit tips.

By using additive manufacturing, there is a vast degree of more flexibility in terms of gas channel design and internal fluid flow paths, etc. This allows for closer formation between the gas channels and the coolant channels as well as more compact design of other integral features formed in the gas injector 300 to allow for efficient gas distribution and/or mixing in certain embodiments.

As mentioned, in one embodiment, the gas injector 300 is suitable for nitride application and can be used to deposit high-quality GaN films for multiple applications.

The AM injector 300 can thus comprise a 3D printed component whose primary function is to precisely deliver the gaseous precursors to the wafer surface. It retains the basic architecture of the traditionally manufactured injector i.e., it delivers the two primary precursors using alternating linear channels. However, it has been completely re-designed to take advantage of Additive Manufacturing (AM). The result is a component that combines three key sub-assemblies —the injector, flow flange and viewport—from the traditional design into a single printed part. This eliminates hundreds of individual parts required to create these sub-assemblies. FIG. 19 illustrates this drastic reduction. The simplification afforded by additive manufacturing (AM) addressees several deficiencies of the previous design including,
Significant reduction in cost and lead-time.
Simplification of initial assembly process
Bottom side gas inlets that allow for the injector to be lifted without disconnecting gas lines (especially helpful in a glovebox).
Reduction in injector vibration
Optimization of strength-to-weight ratio
Elimination of internal leak paths
   The AM injector 300 also has the following additional features for improving performance:
1. A wider viewport for better optical access.
2. Larger injector water-cooling channels.
3. Addition of a “shutter purge” flow zone.

The last two features highlight how AM has improved performance by optimizing existing injector features. In the traditional injector 1, the water channels 5 are small and do not extent to the injector tips leading to overheating of the gases at the exit faces (FIG. 20A). AM has enabled the creation of large water channels 314 (FIG. 20B) that extend close to the tips, resulting in the reduction of the gas exit temperature which is critical for the process.

Similarly, in the traditional injector the area adjacent to the shutter often has flow re-circulation which leads to heavy particle deposition on the shutter. This results in the shutter being a major source of defects due to its proximity to the wafer. The addition of a purge in this area enables the suppression of eddies near the shutter, thus reducing deposition. Inclusion of a shutter purge in a traditional injector would be cost-prohibitive which again highlights how AM enables the realization of advanced ideas that improve capabilities.

### Heated Sidewall

In at least one embodiment (e.g., FIG. 1), the growth zone with the reaction chamber 110 is a so called active hot wall which means the area is heated up to approximately 1750° C. For example, as described below, the growth zone can be heated up by resistance filaments placed around the TaC or SiC coated graphite growth cell. The substrate can consist of a typically monocrystalline SiC wafer that is placed on rotating disc driven by a gas foil principle as described herein.

In at least some of the gas injector embodiments described herein, the gas inlet is partly dipping into the growth cell within the reaction chamber 110. A surrounding graphite liner with a gap to the injector avoid a direct radiation from the hot graphite into the stainless steel/Inconel/Hastelloy made injector.

The distance to the rotating substrate must be optimized in the means of getting the maximum growth rate in flow direction shortly before the front of the substrate for starting the depletion. It also should be a very steep starting with the maximum as the distance with upfront parasitic deposition will be reduced. This is dependent on the gas concentration, the mixing of precursor with SiH₄ and C₃H₈ in this case and the reaction including transient time of the species in the hot environment.

As shown in FIGS. 1-2 and according to one embodiment, the reaction chamber 110 comprises a hot wall reactor and the sidewall 119 comprises a heated sidewall 119. Deposition can also build up on the sidewalls of the reactor and the use of heated sidewalls serves to reduce the degree of deposition. For example, injection of HCl/H₂ through the ceiling (as described herein) along with active heating of the sidewalls to approximately 1800° C. keeps the deposition rate on the sidewalls to less than 10% of the growth rate on the wafer. Heating of the sidewalls also improves the temperature uniformity of the wafer along a direction that is perpendicular to the flow direction. Temperature uniformity along the flow direction is adjustable using multi-zone heating.

One or more sidewall heaters are provided for heating the sidewall 119.

In one embodiment, the heated sidewalls 113 are maintained at temperatures to ˜1800° C. keeps the deposition rate on the sidewalls 113 to <10% of the growth rate on the wafer 10. Heating of the sidewalls 113 also improves the temperature uniformity of the wafer 10 along a direction that is perpendicular to the flow direction. Temperature uniformity along the flow direction is adjustable using multi-zone heating.

The wafer temperature uniformity is controlled by the variation in the reactor cell temperature both along the flow direction and perpendicular to the flow direction. In the flow direction, multiple zones of heating (e.g., 3) can be used to create a temperature profile on the reactor cell that is high or low at the center of the wafer relative to the edge of the wafer. This controllability is required to compensate for heat losses from the wafer edge and to optimize the doping profile so that the shape of the doping profile matches the shape of the growth profile across the wafer. When the profiles are matched, the device characteristics are uniform across the wafer.

In a direction that is perpendicular to the flow direction, the wafer temperature is higher in the center relative to its edge. This is due to heat loss from the sidewalls of the reactor that cool the reactor sidewalls relative to the actively heated ceiling and floor of the reactor cell. The sidewalls are indirectly heated by the heaters for the ceiling and the floor. By adding heaters along the sidewall, the wafer temperature uniformity in the direction perpendicular to the flow is significantly improved. The sidewall heaters can be separate or extensions of the floor and ceiling heaters 150 that are placed adjacent to the sidewalls 119.

Thus, the system described herein includes multiple independently controlled heaters surrounding the reactor cell to control the temperature and temperature distribution on various heater surfaces which yields the benefits described herein.

### Heated and Purged Ceiling

In the system 100, the ceiling of the reaction chamber defined by the ceiling top plate 155 and ceiling showerhead plate 157) is heated and can include a showerhead architecture for injecting purge gases into the reaction chamber 110. More particularly, as described herein, carrier and/or etching gases can be injected through showerhead holes formed in the ceiling into the reaction chamber 110. In FIG. 1, a ceiling showerhead plate 157 is illustrated through which the showerhead holes are formed.

At the top of the reaction chamber 110 there can be a lid that is defined by a top wall with water-cooling for temperature control. The top wall also includes through ports that pass completely through the top wall and other openings for receiving related equipment as described herein. The top wall can thus include an internal chamber (annular space) in which water is circulated. The top wall includes an inner surface or face. The lid can thus be water-cooled.

A ceiling heater assembly 150 is provided and can be positioned between the top wall and the hollow interior of the reaction chamber 110 that contains the wafer carrier 260 and is disposed along the inner face of the top wall. The ceiling heater assembly 150 can include one or more support brackets that are coupled to the inner face. The illustrated ceiling heater assembly 150 can be a resistance 3-zone heater; however, it can equally have another type of construction. FIG. 1 generally shows the ceiling heater assembly 150 with a ceiling top plate 155 disposed below the ceiling heater assembly 150.

The ceiling heater assembly 150 is intended to heat the ceiling of the system 100. More particularly, in the exemplary embodiment discussed herein, the ceiling heater assembly 150 operates at higher temperatures than the temperatures of the heater (discussed herein) that heats the susceptor.

The ceiling of the system 100 can be formed of a top ceiling plate (plate 155) and a lower ceiling plate, in the form of the ceiling showerhead plate 157, that is spaced from the top ceiling plate. There is an open space formed between the top ceiling plate 155 and the ceiling showerhead plate 157. This open space can be thought of as being a gas manifold that distributes gas and permits gas to being injected into the reaction chamber 110. The open space is a rectangular cavity or an annular cavity depending on the type (and shape) of reactor.

The top ceiling plate 155 is configured and intended to absorb energy from the RF heater (which can be in the form of an RF ceiling heater coil) or a resistance heater which operates at a higher temperature as the ceiling plate.

The ceiling showerhead plate 157 includes a plurality of showerhead holes that communicate directly into the reaction chamber 110. Gases that are injected into the open space flow throughout the open space and exit through the showerhead holes. The showerhead holes can be formed in different patterns to allow the uniform distribution of the gases into the reaction chamber 110.

As described herein, the showerhead design permits ceiling purging and more particularly, the showerhead in the ceiling permits injection of carrier gas (H₂, N₂, Ar or a combination thereof) and for some applications, injection of an etching gas (e.g., HCl, Cl₂, TBCl, etc.).

The ceiling of the system 100 is mounted to the lid using suitable mounting structures. For example, an outer support ring and an outer intermediate ring can be used to mount the ceiling heater assembly to the lid. The outer intermediate ring is located radially inward from the outer support ring. These rings can be formed of quartz.

The ceiling of the system 100 is actively heated with a heat source separate from a susceptor heating system. In accordance with one aspect of the present system 100, the operating temperature of the ceiling heater assembly 150 is different than bottom (susceptor) heater assembly that heats the wafer carrier. Therefore, the temperature gradient between the ceiling and the susceptor holding the substrate can be reduced to suppress the convection by temperature gradient towards the ceiling.

For example, the operating temperature of the ceiling heater assembly 150 is higher than the operating temperature of the bottom (susceptor) heater assembly. For example, the operating temperature of the ceiling heater assembly 150 can be between 600° C. and 1200° C., 700° C. and 1100° C., 1600° C. and 1800° C., while the operating temperature of the bottom heater assembly is between 600° C. to 900° C., 700° C. and 1400° C., 1500° C. and 1700° C. The ceiling heater can also be set so that the temperature of the ceiling is lower than the susceptor which might be beneficial for the growth of certain materials within a stack.

The gas purging results from the introduction of gases into the reaction chamber 110 through the ceiling (showerhead holes in the ceiling showerhead plate 157). In one embodiment, one or more showerhead gas modules can be provided along the lid and pass through the ports formed through the top wall and passes through a port formed in the top ceiling plate. In this way, one or more gases, such as a carrier gas, such as H₂/Ar, and/or an etching gas, such as HCl, are directly injected into the open space and then exit through the showerhead holes into the reaction chamber 110 according to a desired, predefined pattern.

The gas injector 120 (e.g., a lateral gas injector as shown in FIGS. 1 and 2) in conjunction with reduced deposition on the walls of the reactor cell results in good uniformity. The growth rate reduces near-linearly from the leading edge of the wafer to the trailing edge of the wafer. The growth rate is relatively uniform in a direction perpendicular to the flow.

The combination of an actively heated and purged ceiling, HCl/H₂ injection through the gas injector 120, and maintaining the sidewalls in the range of (approximately) 1800° C. results in a significantly lower growth rate on reactor surfaces. The growth rate is near zero over most of the reactor surfaces and deposition is confined to a short region along the sidewall 113 of the reactor. This can be further reduced through optimization of the reactor cell geometry and the distribution of gas flows through the injector and the ceiling. Reduction of deposition on various surfaces also reduces the likelihood of cracking of coated surfaces due to the stress induced by thick deposited films further increasing the lifetime of the parts.

The peak growth rate on the floor of the reactor can be ˜2× higher than the average growth rate on the wafer. Accordingly, portions of the floor that get excessively coated such as the carrier, wafer, wafer support ring, and satellite disc must be removed by the automated handling system. In accordance with the present disclosure, the systems described herein address and overcome this problem by providing a reactor floor that is removable for easy cleaning thereof.

It will be appreciated that the ceiling construction described above, and the operating parameters discussed above are only exemplary and not limiting of the scope of the present disclosure.

### SiC Application

In the case of SiC epitaxy, the ceiling temperature of the systems disclosed herein is heated between 1600° C. and 1800° C. due to heating by for example an RF pancake coil (RF ceiling heater coil). The temperature of the contact to the quartz should not exceed 1200° C. Therefore, at least two intermediate rings can be in between the ceiling and the quartz support to lower the temperature and additionally reduce the thermal stress. The material selection for the ceiling and the susceptor is more restrictive in SiC applications because of the high temperature and the interaction with the carrier and process gases. In the case of SiC epitaxy, there will be only graphite with TaC coating or SiC coating or solid SiC. The limit of SiC coating is removal of the coating via sublimination if it comes into proximity with a colder surface.

### GaN Application

For a GaN application, the ceiling temperature is heated between 700° C. and 1100° C. (or lower temperatures) due to heating by the RF pancake coil (RF ceiling heater coil). The material selection for the ceiling and the susceptor is less restrictive but nevertheless it should be protected from hot ammonia which requires a protective coating of the graphite. The preferred coating is SiC, but TaC or pyrolytic boron nitride can alternatively be used as a coating. Also, solid SiC can be used for some parts such as cover plates, satellites, satellite rings, etc.

The susceptor can also be heated to 700° C. and 1400° C. by resistive heating using filaments that are preferably made of W or Re. Resistive heating provides multiple zone temperature control which is not possible with RF heating.

### GaAs/InP Application

For GaAs/InP application, the temperature of the ceiling can be between 600° C. and 1200° C. (or lower temperatures) using RF with the pancake coil (RF ceiling heater coil). The material selection for the ceiling and the susceptor is less restrictive and preferably is highly purified graphite.

### GaAs/InP Application

Resistive heating up to 600° C. to 1100° C. using filaments that are preferably made of pure graphite can be used.

It will be appreciated that the above values are only exemplary in nature of certain application and not limiting of the scope of the present disclosure.

### Susceptor Heating Assembly

A susceptor heating assembly 151 is provided for heating the wafer carrier and is located beneath the wafer carrier.

The susceptor heating assembly 151 typically has a different construction than the ceiling heater assembly 150. More particularly, for the planetary cross-flow architecture, the susceptor heating assembly can have an outer susceptor heater coil and an inner susceptor heater coil that is coupled to the outer susceptor heater coil. The outer susceptor heater coil is located radially outward from the inner susceptor heater coil. The outer susceptor heater coil can include a water inlet for delivering water into the coil and a water outlet for withdrawing water from the coil. Similarly, the inner susceptor heater coil includes a water inlet for delivering water into the coil and a water outlet for withdrawing water from the coil. Alternatively, it can have a different construction than the aforementioned one.

### Gas Injection into the Reaction Chamber

As mentioned herein, gases can be injected into the reaction chamber 110 in at least two different locations and by at least two different means (i.e., two different injector types).

First, the ceiling showerhead plate 157 permits injection of one or more carrier gases and/or one or more etching gases. The showerhead design allows for these gases to be injected through the heated ceiling into the reaction chamber 110 in a controlled manner. Second, the lateral gas injector 120 acts to inject the reactant gases such that the reactant gases flow within the reaction chamber 110 over a single wafer substrate 10 or wafer substrates 10 on the satellites. Alternatively, the gas injector can comprise gas injector 200 when a planetary wafer arrangement is used.

### Parasitic Deposition on the Ceiling

As mentioned, one of the primary disadvantages of conventional planetary reactor systems is the parasitic deposition on the ceiling. Parasitic deposition can cause particle generation and alter the thermal balance within the reactor which leads to process drift. To avoid this, in-situ chamber etching is often used but this will increase the total cycle time for a production run. In-situ cleaning typically reduces component lifetimes and therefore increases the costs of consumables. In-situ etching is impractical for certain materials, such as SiC, that are difficult to etch in typical in-situ cleaning gases, such as Cl₂, HCl and NF₃.

Additionally, the parasitic deposition consumes precursor materials which will not end up in the active layer on the substrate. This reduces the total precursor usage efficiency and limits the process window for good uniformity (e.g., for thickness, composition and doping) on the wafer.

The system 100 disclosed herein is configured to avoid or significantly minimize the parasitic deposition on the ceiling. This can eliminate or reduce the need for in-situ cleaning, enhance component lifetimes, increase growth rates, increase gas usage efficiency, and broaden the process window for deposition uniformity on the wafer. Elimination or reduction of in-situ cleaning shortens the cycle time and extends the preventative maintenance cycle.

The exemplary system 100 uses a combination of flows introduced by vertical (showerhead design) and horizontal (lateral gas injector 120) gas inlets.

### Exhaust

The system 100 of FIG. 1 includes a peripheral exhaust port 160 for exhausting gases from the exhaust chamber 110. In combination with the controlled sidewall temperature, the peripheral exhaust port 160 is configured to limit parasitic deposition and avoid exhaust clogging. It will be appreciated that any number of different peripheral exhausts can be used in the system 100. As shown in FIG. 1, the exhaust system can include an exhaust liner 162 and an exhaust tube 163 that leads to the exhaust port 160 that is operatively connected to a vacuum system or some other exhaust means. There can also be a shutter 161 that opens the path for unloading and loading the removable parts. The shutter 161 thus gives access to the end effector 400 while loading and unloading.

### Gear Box

A conventional gear box can be used in the single wafer design of FIG. 1.

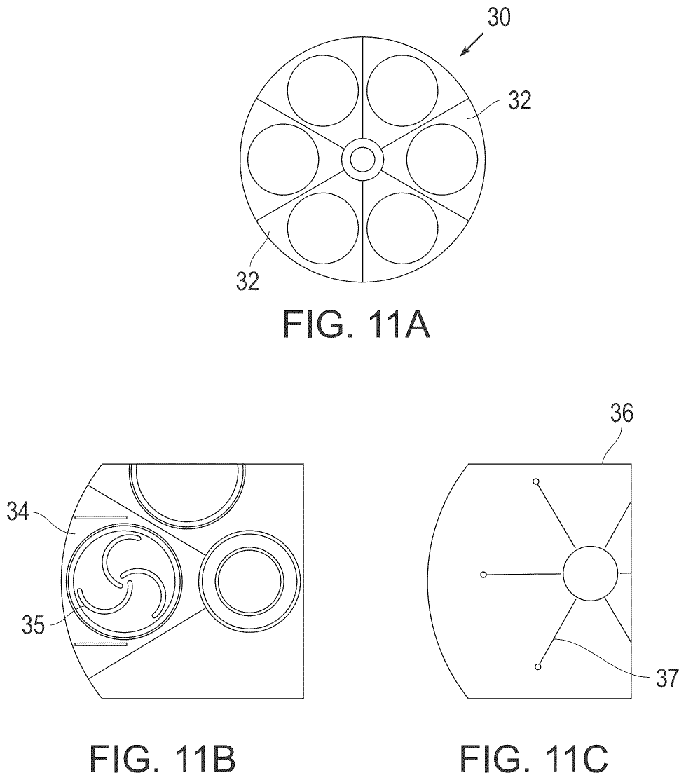

As mentioned with respect to the drive mechanism of the multi-wafer systems of FIGS. 11A-C and 9, the wafer carrier and the satellites are driven in such a way that each can be independently controlled and rotated at least in one embodiment. In particular, the wafer carrier (wafer carrier body) is configured to rotate relative to the base at a first rate and the individual satellites mounted within the substrate carrier can rotate relative to the base at a second rate different than the first rate. In one embodiment, the wafer carrier rotates between about 50 RPM and 400 RPM, while the satellites rotate between 20 RPM and 40 RPM; however, this is merely one example. The planetary configuration of the mechanical drive can use a single motor to drive both the satellites and the wafer carrier though reduction gears can be used as described herein. In one embodiment, the wafer carrier and the satellites rotate in the same direction. It will be appreciated that in other applications, the speeds of the wafer carrier and satellites can be different from the aforementioned ranges.

Gear boxes can be operatively coupled to a pair of satellites for rotating them at a desired speed. The gear boxes can sit on the bottom plate of the system 100. These same gear boxes can function to rotate the wafer carrier as well.

### Gas Driven Rotation Drive

U.S. Pat. Nos. 6,878,395 and 6,983,620, each of which is hereby expressly incorporated by reference in its entirety, describe and illustrate a gas drive with single satellite gas control that can be modified and implemented in the systems described herein. Gases are fed into the vacuum tight reaction chamber by a multiple gas feed through a hollow shaft ferrofluidic. Each gas channel can be controlled by an MFC (mass flow controller) and supplied to a single satellite. The gas is supplied to a hollow pin to the individual gas drive for each satellite.

Modeling confirms growth rate and uniformity are achievable on 200 mm wafers for a variety of materials. Growth of SiC, GaN, InGaN, GaAs, InAlP, and InGaAsP were evaluated.

Deposition on ceiling can be eliminated (SiC) or reduced by >100× (for III-N and As/P) compared to conventional crossflow reactors. Gas usage efficiency and growth rates are comparable or higher than crossflow planetary. Carrier rotational speeds is about 5-20 RPM are adequate for many applications. If higher speeds (e.g., 50-400 rpm) are desired, the gearbox drive mechanism may have to be used.

FIG. 1 generally illustrates one exemplary gas drive mechanism incorporated into the system 100. More specifically, a hollow shaft 180 is shown to feed a gas into the vacuum tight reaction chamber 110. For example, the feed gas can be in the form of Ar or H₂ or a mixture of Ar and H₂. When the system comprises a multi satellite arrangement, the gases are fed into the vacuum tight reaction chamber by a multiple gas feed. For example, if there are eight satellites, there can be eight separate satellite gas feeds (which can be controlled by the MFC). Each gas channel can be controlled by the MFC and supplied to a single satellite. The gas can be supplied to a hollow pin to the individual gas drive for each satellite. In this embodiment, the system thus utilizes a gas driven rotation drive mechanism to control the rotation of each satellite and the wafer carrier.

In gas driven drive mechanism (gas foil rotation), the gas flows through gas distribution channels with a flow direction that is directed circumferentially, so that it not only raises the substrate holder from a bearing surface, but also imposes a rotary momentum on the substrate holder, so that the holder is driven in rotation. Accordingly, in gas driven drive mechanism, the susceptor is formed to include gas distribution channels that are arranged in spiral from a center point of the relevant susceptor section and as a result, the fed-in gas flow is set into a rotational motion which drives the substrate holder into rotation.

FIGS. 11A-C shows one exemplary gas driven drive mechanism (gas foil rotation) structure for a multi-wafer reactor design. In particular, FIGS. 11A-C illustrate a separated (segmented) carrier that is formed of a cover plate 30. In a segmented carrier design, the cover plate 30 (FIG. 11A) is segmented into a plurality of discrete segments or sections 32 (“pie shaped sections”) with each section 32 having an opening to accommodate one satellite/satellite ring (a substrate holder). FIGS. 11B and 11C illustrate a two-piece susceptor with FIG. 11C illustrating a bottom susceptor part 34 that includes a plurality of gas distribution channels 35. In the illustrated embodiment, the plurality of gas distribution channels 35 are arranged in a spiral manner. FIG. 11B illustrates a top susceptor part 34 that can be thoughts of as including a plurality of surface sections (zones) each of which is aligned with one opening formed in the cover plate 30 and thus, each surface section has an associated satellite/satellite ring. Within each surface section (zone), there are spiral gas distribution channels 35 that are arranged such that the fed-in gas flow is set into a rotational motion which drives the substrate holder into rotation. The area(s) in which the spiral gas distribution channels 35 represents a bearing surface. FIG. 11C shows a bottom susceptor part 36 with gas distribution channels 37 (arranged in a spoke-like pattern).

While FIGS. 11A-C illustrate a cover plate 30 that is segmented, it will be appreciated that the above-described gas driven drive mechanism (gas foil rotation) can be equally implemented in a non-segmented cover plate design, as well as the other systems described herein, such as system 100 of FIG. 1. In other words, gas foil rotation can be incorporated into both single wafer systems as well as multi-wafer planetary systems.

As previously mentioned, the present disclosure is directed to a gas injector for use in a chemical vapor deposition system and more particularly, is directed to a gas injector formed as a monobloc. For formation of the gas injector as a monobloc results from the gas injector being formed using an additive manufacturing process. All of the internal features, including channels, flow modifying features, etc., are formed as voids within the monobloc. The use of additive manufacturing allows for the internal features to have complex design and be formed in a more compact space, both of which are very difficult if not impossible using conventional fabrication techniques. Modeling software is therefore used to develop and create the design of the internal gas and coolant channel architecture without the significant limitations that existed in prior manufacturing techniques of combining multiple parts and/or boring metal parts to form internal channels.

It will also be appreciated that the types of gas injectors disclosed and illustrated herein are merely exemplary in nature and the teachings of the present disclosure and in particular, the use of additive manufacturing to form a monobloc gas injector can be applied to other types of gas injectors.

Various embodiments of systems, devices, and methods have been described herein. These embodiments are given only by way of example and are not intended to limit the scope of the claimed inventions. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the claimed inventions.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35U.S.C. § 112(f) are not to be invoked unless the specific terms “means for” or “step for” are recited in a claim.

1. A chemical vapor deposition system comprising:
a reaction chamber having an exhaust system;
a gas injector having at least one injection zone; and
a heater assembly for heating the reaction chamber;
wherein the gas injector is additively manufactured to form a unitary body.

2. The chemical vapor deposition system of claim 1, wherein the gas injector comprises a horizontal cross flow gas injector that is positioned at one end of the reaction chamber.

3. The chemical vapor deposition system of claim 1, wherein the at least one injection zone of the gas injector includes at least three and up to five gas outlet areas in a vertical direction and up to three horizontal gas outlet zones.

4. The chemical vapor deposition system of claim 1, wherein the at least one injection zone of the gas injector includes three horizontal gas outlet zones in the form of a left zone, a center zone and a right zone and further includes a first vertical zone, a second vertical zone, a third vertical zone and a fourth vertical zone.

5. (canceled)

6. (canceled)

7. The chemical vapor deposition system of claim 1, wherein each injection zone of the at least one injection zone is configured to generate a laminar and uniform flow pattern into a growth zone defined in the reaction chamber.

8. The chemical vapor deposition system of claim 1, wherein the gas injector includes one or more gas channels formed integrally as voids within the unitary body.

9. The chemical vapor deposition system of claim 1, wherein each of the one or more gas channels is open along a rear end of the gas injector for receiving a gas or gas mixture and is open along an opposite front end of the gas injector that is disposed within the reaction chamber.

10. The chemical vapor deposition system of claim 9, wherein the gas injector includes integral features that impart horizontal and vertical flow to gas exiting the gas injector through one of the one or more gas channels.

11. The chemical vapor deposition system of claim 10, wherein the features comprise baffles that impart horizontal flow to the gas and fins that impart vertical flow to the gas.

12. The chemical vapor deposition system of claim 11, wherein the baffles are disposed upstream of the fins to impart horizontal flow to the gas before vertical flow is imparted to the gas.

13. The chemical vapor deposition system of claim 11, wherein one gas injection nozzle is defined between two chamfered edges of two adjacent fins, the two chamfered edges taper outwardly in a direction away from the baffles.

14. The chemical vapor deposition system of claim 1, wherein the gas injector includes a coolant circuit formed integrally as a void within the unitary body.

15. (canceled)

16. (canceled)

17. (canceled)

18. (canceled)

19. (canceled)

20. The chemical vapor deposition system of claim 1, wherein the reaction chamber includes heated sidewalls.

21. The chemical vapor deposition system of claim 1, further including:
a wafer carrier; and
a gas driven drive mechanism for rotating the wafer carrier, the wafer carrier having gas distribution channels with a flow direction that is directed circumferentially so that it imposes a rotary momentum on the wafer carrier.

22. The chemical vapor deposition system of claim 1, wherein the gas injector comprises a vertically movable gas injector positioned centrally and over a multi-wafer carrier within the reaction chamber, the gas injector including a plurality of injection zones stacked in a vertical arrangement.

23. The chemical vapor deposition system of claim 22, further including a center gas flow port positioned in a center of the multi-wafer carrier and the heater assembly is positioned beneath the multi-wafer carrier.

24. (canceled)

25. (canceled)

26. (canceled)

27. (canceled)

28. The chemical vapor deposition system of claim 1, wherein the reaction chamber is defined by sidewalls and the system further includes a sidewall heater for actively heating the sidewalls to approximately 1800° C.

29. A method comprising:
designing a gas injector to includes a plurality of separate, independent internal structures, wherein the plurality of internal structures comprise a gas channel structure and a gas nozzle structure and a coolant circuit; and
building the gas injector by a layer-by-layer additive manufacturing process;
wherein the plurality of internal structures are defined by voids formed in a unitary monobloc that defines the gas injector.

30. The method of claim 29, wherein the layer-by-layer additive manufacturing process comprises powder based, selective laser sintering, or free-form additive manufacturing.
